(19) United States
(12) Patent Application Publication
(10) Pub. No.: US 2026/0371933 A1
(43) Pub. Date: Nov. 19, 2026

(54) PIEZOELECTRIC SINGLE CRYSTAL TRANSDUCER ELEMENT AND A METHOD FOR ITS MANUFACTURING

(71) Applicant: CHAIRMAN, DEFENCE RESEARCH AND DEVELOPMENT ORGANIZATION, New Delhi (IN)

(72) Inventors: Elangovan VARADARAJAN, Chennai (IN); Chandramohan MANIKANDAN, Chennai (IN); Venkatachalam NATARAJAN, Chennai (IN); Sarveswaran GANESAMOORTHY, Kalpakkam (IN); Ramaiyan Mahadevan SARGUNA, Kalpakkam (IN); Palanimuthu VIJAYAKUMAR, Kalpakkam (IN); Prabu Amaladass EDWARD, Kalpakkam (IN); Mani AWADHESH, Kalpakkam (IN); Shekar Nagar Venkataraman CHANDRA, Kalpakkam (IN); Abisekaraj Isaac Abraham REGIVA, Visakhapatnam (IN)

(73) Assignee: CHAIRMAN, DEFENCE RESEARCH AND DEVELOPMENT ORGANIZATION, New Delhi (IN)

(21) Appl. No.: 19/138,757

(22) PCT Filed: Dec. 26, 2023
(86) PCT No.: PCT/IB2023/063234

§ 371 Date: Jun. 13, 2025

(30) Foreign Application Priority Data
Jan. 31, 2023 (IN) 202311006223

(51) Int. Cl. H10N 30/853; H10N 30/045; H10N 30/078; H10N 30/086; H10N 30/088

(52) U.S. Cl. CPC H10N 30/8554; H10N 30/045; H10N 30/078; H10N 30/086; H10N 30/088

(57) ABSTRACT

The present disclosure relates to a piezoelectric single crystal transducer element and a method for its manufacturing. The piezoelectric single crystal transducer element comprises PZN-PT single crystal and at least one metallized layer on the crystal. The transducer element is adapted to use in a high-frequency underwater acoustic transducer as an integral part of underwater SONAR, ultrasound medical transducers, low-field driven actuators, electroacoustic transducers and piezoelectric based MEMS devices. The method of the present disclosure is a convenient method for obtaining an array of piezoelectric single crystal transducer elements used in a high-frequency underwater acoustic transducer.

### FIELD

The present disclosure relates to piezoelectric devices. Particularly, the present disclosure relates to piezoelectric single crystal transducer element and a method for its manufacturing.

### DEFINITIONS

As used in the present disclosure, the following terms are generally intended to have the meaning as set forth below, except to the extent that the context in which they are used indicate otherwise.

The term “piezoelectric material” refers to materials that can produce electric energy upon application of mechanical stress.

The term “relaxor material” refers to a ferroelectric material that exhibits high electrostriction.

The term “PZN-PT” refers to a material Lead Zinc Niobate: Lead Titanate.

The term “An array of piezoelectric single crystal transducer elements” refers to [001] oriented (1−x) PZN-xPT single crystal at morphotropic phase boundary composition (x=9%) with domain-engineered configuration fabricated into an array of transducer elements.

The term “relaxor” refers to a ferroelectric material that exhibits high electrostriction. It is a property of all insulators, or dielectrics, that causes them to change their shape under the application of an electric field.

The term “orientation along [001] crystallographic direction” refers to the orientation of a surface or a crystal plane as to how the plane (or indeed any parallel plane) intersects the main crystallographic axes of the solid. The orientation is defined by the Miller Indices (hkl), which are a set of numbers which quantify the intercepts and are used to uniquely identify the plane or surface.

The term “remnant polarization” refers to the amount of polarization that remains in the material after the electric field is removed from the material.

The term “coercive field” refers to the field necessary to bring the polarization value to zero. The term “unipolar strain” refers to the strain in response to the single polarity of the electric field. i.e., unipolar mode.

The term “longitudinal piezoelectric strain coefficient” refers to a ratio of strain (in longitudinal direction) produced by the applied electric field in the longitudinal direction.

The term “electromechnical coupling factor” of a piezoelectric material refers to the conversion ability between electric and mechanical energy and vice versa.

The term “longitudinal piezoelectric voltage coefficient” refers to a ratio of the electric field (in longitudinal direction) produced to the mechanical stress applied in the longitudinal direction.

The term “1-3 piezo composites” refers to piezoelectric composites that are a combination of an active piezoelectric material and a passive material such as polymer or epoxy. Connectivity is defined as the number of dimensions through which a material is continuous. The connectivity of a piezoelectric composite is shown as a combination of two numbers such as 1-3, 2-2, 0-3 where the first digit represents the active material and the second digit represents the passive material. In 1-3 piezo composites, piezoelectric materials are continuous in one direction.

The term “back reflection Laue diffraction technique” refers to a method mainly used to determine the orientation of large single crystals where the white radiation is allowed to fall on the fixed crystal and the white radiation reflected from or transmitted through a fixed crystal are recorded in a photographic film. There are two types of the Laue method (i) back reflection Laue and (ii) Transmission Laue method. In the back-reflection method, the film is placed between the x-ray source and the crystal. The beams which are diffracted in a backward direction are recorded.

The term “DC magnetron sputtering” or “Direct current (DC) sputtering” refers to a thin film deposition technique that uses ionised gas molecules to vaporise (sputter) molecules off the target material into plasma. Sputtering is one of the physical vapor deposition processes in which atoms are ejected from the source (target) by the bombardment of high energetic ions. The DC sputtering system is composed of pair of planar electrodes. The target material acts as a cathode and the substrates are placed on the anode. When the inert gas is passed inside the sputtering chamber and several kilovolts of DC voltage is applied between the electrodes, the glow discharge is initiated. The inert gas ions in the glow discharge are accelerated at the cathode and sputter the target resulting in the deposition of thin film on the substrates.

The term “field cooling technique” refers to a technique wherein the temperature of the sample/specimen such as crystal is reduced to room temperature in the presence of the poling field.

### BACKGROUND

The background information herein below relates to the present disclosure but is not necessarily prior art.

Piezoelectric material with enhanced piezoelectric performance is vital to meet the forever-growing demands of advanced piezoelectric devices in primarily underwater sonar, medical ultrasound transducers, low-field driven actuators, electroacoustic transducers and the like. The global piezoelectric devices market is ever increasing which reveals the importance of piezoelectric materials and their implementation in advanced piezoelectric devices.

Relaxor-PbTiO₃ single crystals show exceptionally large piezoelectric responses exclusively at morphotropic phase boundary composition with specific orientation and domain-engineered configuration with the application of an external electric field. However, the growth of a relaxor-PbTiO₃ single crystal is a very difficult process as it comprises multi-components which exhibit complex thermodynamic behaviour and finding an appropriate thermodynamic, chemical and kinetic parameter is a tricky process.

The primary challenge involved in growing large relaxor-PbTiO₃ single crystals is the formation of a defect pyrochlore phase which induces instability in the crystallization process that leads to the generation of point defects like inclusions/voids, polycrystals, and the like. Several other challenges related to the growth of large relaxor-PbTiO₃ single crystals are the volatile nature of PbO at elevated temperatures forming parasitic pyrochlore phase, segregation during crystal growth process induced structural variation across the volume of the grown crystal which creates property variation, crystal growth at high temperature encounters technical barriers, including breakage of platinum crucibles and volatility of PbO etc., and low thermal conductivity (0.01 W/m. K) affecting the transport of latent heat released during the crystallization process, that causes interface instability, defects, inclusions and phase segregation and the like. Conventionally, relaxor-PbTiO₃ single crystals are grown by various crystal growth techniques. The high-temperature solution growth method, also called the flux crystal growth method, is widely adopted for the growth of binary relaxor-PbTiO₃ single crystals because of its inherent ability to grow incongruent melting material or material which is extremely volatile before reaching melting temperature. The conventional flux growth is based on the principle of spontaneous nucleation. The nucleation can be achieved by the solution of a supersaturation state which is reached by a slow cooling process. The shortcomings of the flux crystal growth method are difficulty in controlling spontaneous nucleation, growth of large dimension single crystal, slow growth rate, flux inclusion and crystal orientation.

Further, the major obstacles in the widespread usage of relaxor-PbTiO₃ single crystals in advanced piezoelectric devices are the non-availability of large dimensions and high-quality single crystals.

There is, therefore, felt a need for a piezoelectric single crystal transducer element and a method for its manufacturing that overcomes the above-mentioned drawbacks, or at least provide an alternative solution.

### OBJECTS

Some of the objects of the present disclosure, which at least one embodiment herein satisfies, are as follows:
An object of the present disclosure is to ameliorate one or more problems of the prior art or to at least provide a useful alternative.
Another object of the present disclosure is to provide a piezoelectric single crystal element.
Still another object of the present disclosure is to provide a piezoelectric single crystal transducer element having comparatively larger dimensions.
Yet another object of the present disclosure is to provide a piezoelectric single crystal transducer element having a high longitudinal piezoelectric strain coefficient.
Still another object of the present disclosure is to provide a method for the manufacturing of the piezoelectric single crystal transducer element.
Yet another object of the present disclosure is to provide a simple and effective method for the manufacturing of the piezoelectric single crystal transducer element.
Still another object of the present disclosure is to provide a method for the manufacturing of the piezoelectric single crystal transducer element which controls spontaneous nucleation.
Yet another object of the present disclosure is to provide a method for the manufacturing of the piezoelectric single crystal transducer element which has a comparatively higher yield.

Other objects and advantages of the present disclosure will be more apparent from the following description, which is not intended to limit the scope of the present disclosure.

### SUMMARY

The present disclosure relates to a piezoelectric single crystal transducer element. The piezoelectric single crystal transducer element comprises PZN-PT single crystal having predetermined dimensions, and having an operative top surface and an operative bottom surface, and at least one metallized layer of predetermined thickness on the operating top surface and the operating bottom surface. The crystal is poled along [001] direction.

The present disclosure also provides a method for the manufacturing of piezoelectric single crystal transducer element. In the method, a PZN-PT single crystal is prepared. The PZN-PT single crystal is oriented along a predetermined direction to obtain an oriented PZN-PT single crystal. The oriented PZN-PT single crystal is sequentially diced, lapped and polished to obtain a PZN-PT single crystal having predetermined dimensions, and having an operative top surface and an operating bottom surface. A metallized layer is deposited on the operative top surface and the operative bottom surface of the PZN-PT single crystal having predetermined dimensions to obtain a metallized crystal. The metallized crystal is then poled along the predetermined direction to obtain the piezoelectric single crystal transducer element.

### BRIEF DESCRIPTION OF THE ACCOMPANYING DRAWINGS

The present disclosure will now be described with the help of the accompanying drawings, in which:

FIG. 1 (a and b) illustrate an as-grown PZN-PT single crystal by the method in accordance with the present disclosure;

FIG. 2 illustrates a surface morphology of an as-grown PZN-PT single crystal observed using an optical microscope, in accordance with the present disclosure;

FIG. 3 illustrates (a) diced PZN-PT single crystal elements (b) polished PZN-PT single crystal elements and (c) metallized PZN-PT single crystal elements, in accordance with the present disclosure;

FIG. 4 illustrates an optical microscopic image of (a) diced PZN-PT single crystal elements (b) lapped PZN-PT single crystal elements (c) polished PZN-PT single crystal element in accordance with the present disclosure;

FIG. 5 illustrates a schematic diagram of the optimized method sequence steps for fabricating PZN-PT single crystal transducer element, in accordance with the present disclosure, wherein (a) as grown crystal, (b) dicing, (c) lapping, (d) polishing, (e) Au/Cr electroding, and (f) poling;

FIG. 6 illustrates a Laue diffraction pattern of [001] oriented single crystal element, in accordance with the present disclosure;

FIG. 7 illustrates the X-ray powder diffraction pattern of PZN-PT single crystal, in accordance with the present disclosure;

FIG. 8 illustrates the high-resolution X-ray diffraction rocking curve of [001] oriented PZN-PT single crystal element, in accordance with the present disclosure;

FIG. 9 illustrates the domain structure of [001] oriented PZN-PT single crystal element, in accordance with the present disclosure;

FIG. 10 illustrates a ferroelectric hysteresis loop of PZN-PT single crystal element, in accordance with the present disclosure;

FIG. 11 illustrates a unipolar strain response of PZN-PT single crystal element, in accordance with the present disclosure;

FIG. 12 illustrates an impedance spectra with the phase angle of PZN-PT single crystal element, in accordance with the present disclosure;

FIG. 13 illustrates (a) assembled PZN-PT single crystal transducer array (b) moulded PZN-PT single crystal transducer array, in accordance with the present disclosure; and

FIG. 14 illustrates a graph of receiving sensitivities versus frequency for a comparison of receiving sensitivities of the conventional 1-3 piezocomposite and PZN-PT single crystal transducer element produced in accordance with the present disclosure.

### DETAILED DESCRIPTION

Embodiments of the present disclosure will now be described with reference to the accompanying drawing.

Embodiments are provided so as to thoroughly and fully convey the scope of the present disclosure to the person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, integers, steps, operations, elements, modules, units and/or components, but do not forbid the presence or addition of one or more other features, integers, steps, operations, elements, components, and/or groups thereof. The particular order of steps disclosed in the method and process of the present disclosure is not to be construed as necessarily requiring their performance as described or illustrated. It is also to be understood that additional or alternative steps may be employed.

As used herein, the term “and/or” includes any and all combinations of one or more of the associated listed elements.

The terms first, second, third, etc., should not be construed to limit the scope of the present disclosure as the aforementioned terms may be only used to distinguish one element, component, region, layer or section from another component, region, layer or section. Terms such as first, second, third etc., when used herein do not imply a specific sequence or order unless clearly suggested by the present disclosure.

Piezoelectric material with enhanced piezoelectric performance is vital to meet the forever-growing demands of advanced piezoelectric devices in primarily underwater sonar, medical ultrasound transducers, low-field driven actuators, electroacoustic transducers and the like. The global piezoelectric devices market is ever increasing which reveals the importance of piezoelectric materials and their implementation in advanced piezoelectric devices. Conventionally, relaxor-PbTiO₃ single crystals are grown by various crystal growth techniques. The high-temperature solution growth method, also called the flux crystal growth method, is widely adopted for the growth of binary relaxor-PbTiO₃ single crystals because of its inherent ability to grow incongruent melting material or material which is extremely volatile before reaching melting temperature. Conventional flux growth is based on the principle of spontaneous nucleation. The nucleation can be achieved by the solution of a super-saturation state which is reached by a slow cooling process. The shortcomings of the flux crystal growth method are difficulty in controlling spontaneous nucleation, growth of large dimension single crystal, slow growth rate, flux inclusion and crystal orientation. Further, the major hindrances in the widespread usage of relaxor-PbTiO₃ single crystals in advanced piezoelectric devices are the non-availability of large dimensions and high-quality single crystals.

The present disclosure provides a piezoelectric single crystal transducer element and a method for its manufacturing.

In an aspect, the present disclosure relates to a piezoelectric single crystal transducer element. The piezoelectric single crystal transducer element comprising PZN-PT single crystal having predetermined dimensions and having an operative top surface and an operative bottom surface, and at least one metallized layer of predetermined thickness on the operative top surface and the operating bottom surface. The crystal is poled along [001] direction.

In accordance with the embodiments of the present disclosure, the dimensions of the piezoelectric single crystal are in the range of 35×30×20 mm³ to 40×40×30 mm³. In an exemplary embodiment, the dimensions of the piezoelectric single crystal are 35×30×20 mm³.

In accordance with the embodiments of the present disclosure, the metallized layer comprises at least one metal selected from gold and chromium. In an exemplary embodiment, the metallized layer is a gold layer.

In accordance with the embodiments of the present disclosure, the thickness of the metallized layer is in the range of 250 nm to 350 nm. In an exemplary embodiment, the thickness of the metallized layer is 300 nm.

In accordance with the embodiments of the present disclosure, the transducer element is characterized by having a remnant polarization in the range of 24 μC/cm² to 27.5 μC/cm² at a frequency of 1 Hz. In an exemplary embodiment, the remnant polarization is 26 μC/cm² at a frequency of 1 Hz.

In accordance with the embodiments of the present disclosure, the transducer element is characterized by having a coercive field in the range of 3.5 kV/cm to 4.0 kV/cm at a frequency of 1 Hz. In an exemplary embodiment, the coercive field is 3.8 kV/cm at a frequency of 1 Hz.

In accordance with the embodiments of the present disclosure, the transducer element is characterized by having a longitudinal piezoelectric strain coefficient d₃₃ in the range of 2000 pm/V to 2100 pm/V at a frequency of 1 Hz. In an exemplary embodiment, the longitudinal piezoelectric strain coefficient d₃₃ is 2100 pm/V at a frequency of 1 Hz.

In accordance with the embodiments of the present disclosure, the transducer element is characterized by having electromechanical coupling k₃₃ in the silver mode of vibration is in the range of 73 % to 75 %. In an exemplary embodiment, the electromechanical coupling k₃₃ in the silver mode of vibration is 75 %.

In accordance with the embodiments of the present disclosure, the transducer element is characterized by having a longitudinal voltage coefficient g₃₃ in the range of 42 mV.m/N to 50 mV.m/N. In an exemplary embodiment, the longitudinal voltage coefficient g₃₃ is 48 mV.m/N.

In accordance with the embodiments of the present disclosure, the transducer element is adapted to use in a high-frequency underwater acoustic transducer having a frequency in the range of 100 kHz to 200 kHz for use as an integral part of underwater SONAR, ultrasound medical transducers, low-field driven actuators, electroacoustic transducer and piezoelectric based MEMS devices.

In accordance with the embodiments of the present disclosure, the transducer element when used in high-frequency underwater transducers having a frequency in the range of 100 kHz to 200 kHz shows more than ~10 dB improvement in their receiving sensitivity than the 1-3 piezo composites.

The PZN-PT single crystal of the present disclosure is characterized by having exceptionally high longitudinal piezoelectric strain coefficient d₃₃>2000 pC/N, electromechanical coupling factor k₃₃>90%, low hysteresis strain >1% and high dielectric coefficient ε>5000 at morphotropic phase boundary (MPB) composition with specific orientation and domain engineered configuration. These PZN-PT single crystal shows great promise to replace conventional PZT ceramics in strategic defence applications due to their exceptional properties.

In another aspect, the present disclosure provides a method for manufacturing a piezoelectric single crystal transducer element. In the method, a PZN-PT single crystal is prepared. Thereafter, the PZN-PT single crystal is oriented along a predetermined direction to obtain an oriented PZN-PT single crystal. The obtained oriented PZN-PT single crystal is sequentially diced, lapped and polished to obtain a PZN-PT single crystal having predetermined dimensions, and having an operative top surface and an operative bottom surface. A metallized layer is deposited on the operative top surface and the operating bottom surface of the PZN-PT single crystal having predetermined dimensions to obtain a metallized crystal. The metallized crystal is then poled along the predetermined direction to obtain an array of piezoelectric single crystal transducer elements.

The method is described in detail herein below:
In a first step, a piezoelectric single crystal is prepared, i.e. a PZN-PT single crystal is prepared.

In the preparation of PZN-PT single crystal, predetermined amounts of a lead precursor, a zinc precursor, a niobium precursor and a titanium precursor are mixed to obtain a mixture. The mixture is then placed into a noble metal confinement, followed by placing the noble metal confinement into alumina confinement, having a provision for gas purging. The alumina confinement is then heated to a first predetermined temperature at a predetermined heating rate, and simultaneously a gas is fed at a predetermined flow rate through the alumina confinement, followed by maintaining the first predetermined temperature for a first predetermined time period to obtain a preform. Thereafter, the preform is cooled at a second predetermined temperature at a predetermined cooling rate to obtain the PZN-PT single crystal.

In accordance with the embodiments of the present disclosure, the lead precursor is lead oxide. In an exemplary embodiment, the lead precursor is lead (II) oxide.

In accordance with the embodiments of the present disclosure, the predetermined amount of the lead precursor is in the range of 81.0 mass % to 82.0 mass % with respect to the total amount of the mixture. In an exemplary embodiment, the predetermined amount of the lead precursor is 81.7 mass % with respect to the total amount of the mixture, i.e. ~245 g in 300 g. In accordance with the embodiments of the present disclosure, the zinc precursor is zinc oxide.

In accordance with the embodiments of the present disclosure, the predetermined amount of the zinc precursor is in the range of 4.0 mass % to 4.5 mass % with respect to the total amount of the mixture. In an exemplary embodiment, the predetermined amount of the zinc precursor is 4.2 mass % with respect to the total amount of the mixture, i.e. 12.6 g in 300 g.

In accordance with the embodiments of the present disclosure, the niobium precursor is niobium oxide. In an exemplary embodiment, the niobium precursor is niobium (V) oxide.

In accordance with the embodiments of the present disclosure, the predetermined amount of the niobium precursor is in the range of 13 mass % to 14 mass % with respect to the total amount of the mixture. In an exemplary embodiment, the predetermined amount of the niobium precursor is 13.8 mass % with respect to the total amount of the mixture, i.e. 41.4 g in 300 g.

In accordance with the embodiments of the present disclosure, the titanium precursor is titanium oxide. In an exemplary embodiment, the titanium precursor is titanium (IV) oxide.

In accordance with the embodiments of the present disclosure, the predetermined amount of the titanium precursor is in the range of 0.5 mass % to 1.2 mass % with respect to the total amount of the mixture. In an exemplary embodiment, the predetermined amount of the titanium precursor is 0.6 mass % with respect to the total amount of the mixture, i.e. 1.8 g in 300 g.

In accordance with the embodiments of the present disclosure, the gas is oxygen.

In accordance with the embodiments of the present disclosure, the noble metal confinement is a noble metal crucible with a noble metal lid, wherein the noble metal is at least one selected from platinum and iridium.

In accordance with the embodiments of the present disclosure, the alumina confinement is an alumina crucible with an alumina lid.

In accordance with the embodiments of the present disclosure, the first predetermined temperature is in the range of 1240° C. to 1260° C. In an exemplary embodiment, the first predetermined temperature is 1250° C.

In accordance with the embodiments of the present disclosure, the predetermined heating rate is in the range of 60° C./hour to 80° C./hour. In an exemplary embodiment, the predetermined heating rate is 70° C./hour.

In accordance with the embodiments of the present disclosure, the second predetermined temperature is in the range of 880° C. to 920° C. In an exemplary embodiment, the second predetermined temperature is 900° C.

In accordance with the embodiments of the present disclosure, the first predetermined time period is in the range of 4 hours to 6 hours. In an exemplary embodiment, the first predetermined time period is 5 hours.

In accordance with the embodiments of the present disclosure, the predetermined cooling rate is in the range of 0.9° C./hour to 1.0° C./hour. In an exemplary embodiment, the predetermined cooling rate is 1.0° C./hour.

In accordance with the embodiments of the present disclosure, the predetermined gas flowrate is in the range of 0.7 l/min to 2 l/min. In an exemplary embodiment, the predetermined gas flowrate is 1 l/min.

In accordance with the embodiments of the present disclosure, during the growth of large dimension PZN-PT single crystal, the spontaneous nucleation is controlled, wherein a large dimension (edge length>35 mm) single crystal is grown at the centre of the bottom crucible with stress-free manner. The grown PZN-PT single crystal has the dimensions of 35×30×20 mm³. The weight of the grown crystal is 103 g, which is 71% of the total charge as a starting material. The grown PZN-PT single crystal exhibits a pure perovskite phase by maintaining the specific chemical parameters such as charge-to-flux ratio, flux composition and thermal parameters such as soaking temperature, and heating/cooling rate. The perovskite phase is revealed by powder X-ray diffraction pattern and it is confirmed that PZN-PT single crystal belongs to a tetragonal crystal system.

In a second step, thereafter, the obtained PZN-PT single crystal is oriented along a predetermined direction to obtain an oriented PZN-PT single crystal.

In accordance with the embodiments of the present disclosure, the predetermined direction of orientation is [001].

In accordance with the embodiments of the present disclosure, the orienting is performed using a back reflection Laue diffraction technique.

The backscattered Laue diffraction technique is a method mainly used to determine the orientation of large single crystals where the white radiation is allowed to fall on the fixed crystal and the white radiation reflected from or transmitted through a fixed crystal are recorded in a photographic film. There are two types of the Laue method (i) back reflection Laue and (ii) Transmission Laue method. In the back-reflection method, the film is placed between the x-ray source and the crystal. The beams which are diffracted in a backward direction are recorded.

The single crystal prepared in accordance with the present disclosure has anisotropic property in nature, which exhibits unique properties along the different crystallographic directions and it can be utilised by orienting the single crystal along a specific crystallographic direction.

In a third step, the obtained oriented PZN-PT single crystal is sequentially diced, lapped and polished to obtain a PZN-PT single crystal having predetermined dimensions, and having an operative top surface and an operating bottom surface.

In accordance with the embodiments of the present disclosure, the oriented PZN-PT single crystals are diced into appropriate dimensions fitting with the transducer design by dicing process using a diamond wire saw cutting. Subsequently, diced crystals are lapped using a series of SiC sheets to eliminate the non-uniform surface due to the cutting process. Then, the single crystal is subjected to a polishing process to evade the structural damages in the depth of 500 nm to 50 um from the surface that is induced due to previous dicing and lapping processes.

In accordance with the embodiments of the present disclosure, the oriented PZN-PT single crystal after the dicing, lapping and polishing has predetermined dimensions in the range of 35×30×20 mm³ to 40×40×30 mm³. In an exemplary embodiment, the predetermined dimensions are in the range of 35×30×20 mm³.

In a fourth step, a metallized layer is deposited on the operative top surface and the operating bottom surface of the PZN-PT single crystal having predetermined dimensions to obtain a metallized crystal.

In accordance with the embodiments of the present disclosure, the deposition of a metallized layer is performed by using a DC magnetron sputtering process with power in the range of 80 W to 100 W at room temperature for a time period in the range of 3 minutes to 5 minutes.

DC magnetron sputtering process is one of the physical vapor deposition processes in which atoms are ejected from the source (target) by the bombardment of high energetic ions. The DC sputtering system is composed of pair of planar electrodes. The target material is acts as a cathode and the substrates are placed on the anode. When the inert gas is passed inside the sputtering chamber and several kilovolts of DC voltage is applied between the electrodes, the glow discharge is initiated. The inert gas ions in the glow discharge are accelerated at the cathode and sputter the target resulting in the deposition of thin film on the substrates.

In accordance with the embodiments of the present disclosure, the metal layer of Au/Cr is deposited on the top and bottom surface of PZN-PT single crystal, wherein Au/Cr of thickness 300/30 nm is deposited on both faces of single crystal that is parallel to [001] direction by the DC magnetron sputtering. The nature and thickness of the metal layer that is selected in such a way that the metal layer should not alter the natural electrical properties of the single crystal and should withstand the large electric field applied during poling process.

The chromium interlayer is used for adhering gold over PZN-PT single crystal and the ratio of metal to interlayer is optimized to avoid the delamination of the metal layer.

In a fifth step, the metallized crystal is then poled along the predetermined direction to obtain a piezoelectric single-crystal transducer element.

In accordance with the embodiments of the present disclosure, the poling of the metallized crystal is done by subjecting the metallized crystal to the electrical contact poling process by using a field cooling technique, wherein a poling field is applied in the order of 1.5 times of coercive field in the range of 5.25 kV/cm to 6.0 kV/cm at room temperature.

Field cooling technique is to a technique wherein the temperature of the sample/specimen (here crystal) is reduced to room temperature in the presence of the poling field.

In accordance with the embodiments of the present disclosure, the metallized crystal is poled along [001] orientation; where [001] oriented PZN-PT single crystal in tetragonal phase is poled along [001] direction by electrical contact poling method. The poling conditions are optimized to enhance the piezoelectric and electromechanical properties of PZN-PT single crystal. PZN-PT single crystals are poled at a direct current field of 5.25 kV/cm to 6.0 kV/cm at room temperature for a period of 30 minutes.

Poling is the process by which aligning the electric dipoles i.e., ‘polarization reversal’ in the direction of the external electric field. PZN-PT single crystals have intrinsic anisotropic nature i.e., direction-dependent properties, poling is a vital process where poled along different directions exhibits different electromechanical properties. PZN-PT single crystals poled along its polar direction have ‘mono-domain state’, whereas poled along other than polar direction exists with multiple domain configurations. However, in PZN-PT single crystals with multiple domain configurations possess extraordinarily large piezoelectric coefficients for the longitudinal vibration mode, while crystals with single domain states are found to possess very low longitudinal properties and ultrahigh shear properties. The electric field, temperature and poling duration are three crucial factors which impact the poling process. So, it is essential to optimize the poling condition in order to acquire the optimal piezoelectric properties.

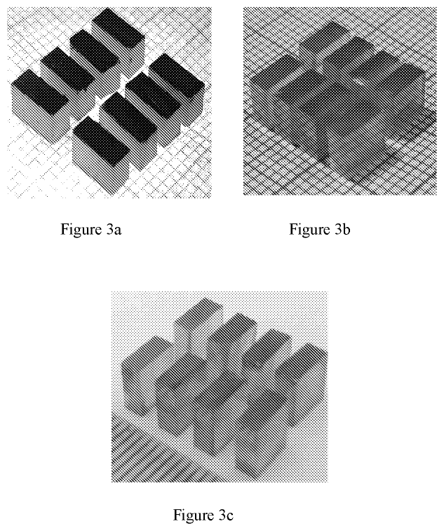

FIG. 3 shows the sequential process used for making the as-grown crystal into transducer elements. The as-grown crystal are oriented into [001] direction followed by dicing (shown in FIG. 3a). Then the diced crystals are lapped (FIG. 3b) and polished (FIG. 3c) to remove the surface defects that occurred during the dicing process.

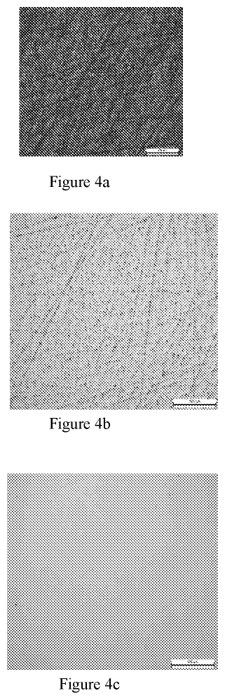

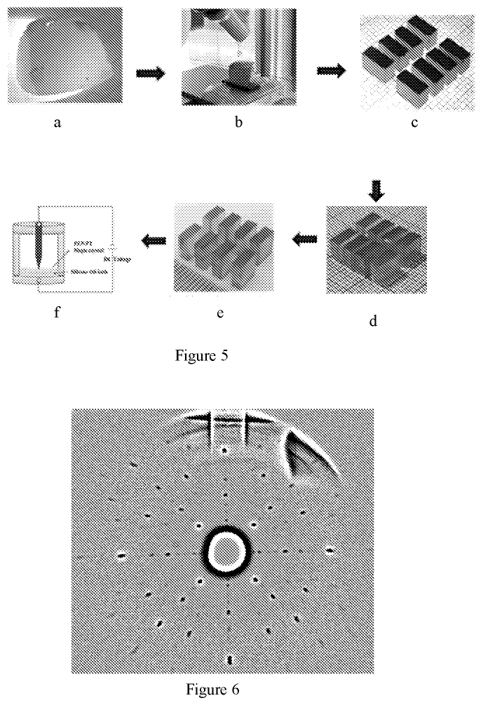

FIG. 4 illustrates an optical microscopic image of (a) diced PZN-PT single crystal elements (b) lapped PZN-PT single crystal elements (c) polished PZN-PT single crystal element in accordance with the present disclosure. FIG. 4 shows the optical microscopic images of PZN-PT single crystal after each process like dicing, lapping and polishing used for converting as-grown crystal into transducer elements. It shows how the surface roughness of the PZN-PT crystal changes after each process.

FIG. 8 shows the high-resolution X-ray diffraction (HRXRD) images of [001] oriented PZN-PT single crystal. It signifies the PZN-PT crystal are in single crystalline nature and oriented in [001] direction. The Full width half maxima value of HRXRD curve indicates the high-quality PZN-PT single crystal in terms of its crystallinity.

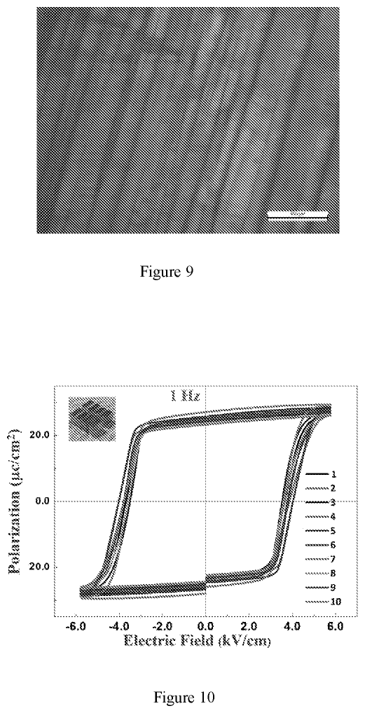

FIG. 9 illustrates the domain structure of [001] oriented PZN-PT single crystal element, in accordance with the present disclosure. Thus, FIG. 9 shows the domain pattern of polished PZN-PT crystal which confirms the PZN-PT single crystal are oriented in [001] direction.

FIG. 10 illustrates a ferroelectric hysteresis loop of PZN-PT single crystal which confirms the PZN-PT single crystal are in ferroelectric nature.

FIG. 12 shows the impedance with phase angle curve of poled PZN-PT single crystal. The impedance spectra confirm the PZN-PT single crystal are in ferroelectric nature and poled along the [001] direction.

In accordance with the embodiments of the present disclosure, the properties of the obtained piezoelectric single crystal transducer element are evaluated according to IEEE standards; where ferroelectric properties are measured using a modified Sawyer-Tower circuit method. The electric field is applied gradually to the PZN-PT single crystal and the well-saturated hysteresis behaviour confirms the ferroelectric nature. The remnant polarization and coercive field of the PZN-PT single crystals are in the range of 24 μC/cm² to 27.5 C/cm² and 3.5 kV/cm to 4.0 kV/cm at the frequency of 1 Hz.

In accordance with the embodiments of the present disclosure, the properties of the obtained piezoelectric single crystal transducer element are evaluated according to IEEE standards; where piezoelectric properties are measured using a unipolar strain method by single beam laser interferometer (SBLI). The unipolar strain of PZN-PT single crystals is measured after poling. The non-hysteresis linear behaviour, confirms the 4R domain-engineered configuration of PZN-PT single crystals. The unipolar strain and longitudinal piezoelectric strain coefficient d₃₃of PZN-PT single crystals are in the range of 0.125 % to 0.128 % and 2000 pm/V to 2100 pm/V at the frequency of 1 Hz.

In accordance with the embodiments of the present disclosure, the properties of the obtained piezoelectric single crystal transducer element are evaluated according to IEEE standards; where the dielectric properties of PZN-PT single crystals are measured using the virtual current method. The capacitance-voltage response shows the inverted butterfly loop which validates the ferroelectric nature of PZN-PT single crystal. The dielectric constant and dielectric loss of PZN-PT single crystals are in the range of 4500 to 5000 and 0.10% to 0.12% at the frequency of 1 Hz.

In accordance with the embodiments of the present disclosure, the properties of the obtained piezoelectric single crystal transducer element are evaluated according to IEEE standards; where the electromechanical properties of PZN-PT single crystals are measured using an impedance analyser. The PZN-PT single crystal electromechanical coupling k₃₃ is measured on the silver mode of vibration and it is in the range of 73% to 75%.

In accordance with the embodiments of the present disclosure, the properties of the obtained piezoelectric single crystal transducer element are evaluated according to IEEE standards; where the longitudinal voltage coefficient g₃₃ of PZN-PT single crystal are in the range of 42 mV.m/N to 50 mV.m/N.

In accordance with the embodiments of the present disclosure, the properties of the obtained piezoelectric single crystal transducer element are evaluated according to IEEE standards; where the as-grown PZN-PT single crystal surface behaviour is observed using an optical microscope. The optical microscope image of as grown PZN-PT single crystal reveals the layer-by-layer growth.

In accordance with the embodiments of the present disclosure, the properties of the obtained piezoelectric single crystal transducer element are evaluated according to IEEE standards; where the PZN-PT single crystal shown pyrochlore free perovskite structure in tetragonal phase, which is confirmed by powder X-ray diffraction pattern.

In accordance with the embodiments of the present disclosure, the properties of the obtained piezoelectric single crystal transducer element are evaluated according to IEEE standards; where the PZN-PT single crystal is oriented along [001] direction by back reflection Laue diffraction technique which reveals crystalline nature and [001] orientation in fourfold symmetry.

In accordance with the embodiments of the present disclosure, the properties of the obtained piezoelectric single crystal transducer element are evaluated according to IEEE standards; where the PZN-PT single crystal structure quality is measured using high-resolution X-ray diffraction method and its full width at half maximum (FWHM) of (001) is in the range of 0.54° to 0.57°.

In accordance with the embodiments of the present disclosure, the properties of the obtained piezoelectric single crystal transducer element are evaluated according to IEEE standards; where the domain structure of [001] oriented PZN-PT single crystal is examined using an optical microscope. The domain structure of as-grown PZN-PT single crystal reveals that domains are aligned parallel to the thickness direction. It confirms that a single crystal is oriented along [001] crystallographic direction.

In accordance with the embodiments of the present disclosure, the properties of the obtained piezoelectric single crystal transducer element are evaluated according to IEEE standards; where the ferroelectric, piezoelectric and electromechanical properties show that the standard deviation is <5% (less than 5%) across the different single crystal element which reveals high compositional homogeneity.

In accordance with the embodiments of the present disclosure, the properties of the obtained piezoelectric single crystal transducer element are evaluated according to IEEE standards; where the grown PZN-PT single crystal weight is about 103 g and it is 71% of the total charge used as a starting material. It confirms that the PZN-PT single crystal grown by novel bottom cooling technique provides better yield in turn reduces the cost of single crystal element.

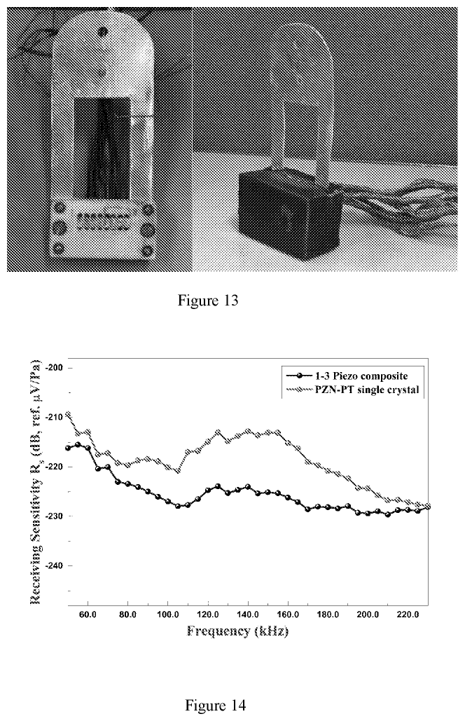

In accordance with the embodiments of the present disclosure, the properties of the obtained piezoelectric single crystal transducer element are evaluated according to IEEE standards, and fabricated into high frequency (100 kHz-200 kHz) underwater acoustic transducer; where the high frequency underwater acoustic transducer is made of PZN-PT single crystal elements. A linear array of PZN-PT single crystal elements are assembled in Teflon housing and the entire array is moulded with acoustically transparent polyurethane. The transducer elements are backed with a pressure-release material followed by hard backing. The single crystal elements are connected with low-noise two-core shielded twisted pair wires (as shown in FIGS. 13a and 13b).

In accordance with the embodiments of the present disclosure, the properties of the obtained piezoelectric single crystal transducer element are evaluated according to IEEE standards, and fabricated in to high frequency (100 kHz-200 kHz) underwater acoustic transducer; and evaluated their performance in the water; where the receiving sensitivity of PZN-PT single crystal based high frequency underwater acoustic transducer shows the 10 dB enhancement than the PZT based 1-3 piezo composites in the frequency range of 100 kHz to 200 kHz.

Further, the present disclosure provides an array of piezoelectric single crystal transducer elements made of [001] oriented PZN-PT single crystal at morphotropic phase boundary composition. These PZN-PT single crystals are grown by the high-temperature flux crystal growth method. By the specific bottom cooling arrangement, the spontaneous nucleation is controlled thereby multi-nucleation is greatly reduced and able to grow the large dimension (>35 mm, edge length) at the centre of the crucible bottom. This novel methodology largely increases the yield which reduces the cost of single crystal growth. Further, the crystal growth system is designed and developed in-house to provide the suitable growth condition for large dimension single crystals which is more economically feasible than the commercially available flux crystal growth systems.

In accordance with the embodiments of the present disclosure, the as-grown single crystal exhibits yellowish-brown colour. PZN-PT single crystal is oriented along [001] crystallographic direction using Laue diffraction pattern to exploit the anisotropic property. The powder X-ray diffraction pattern shows that the as-grown single crystals are in a tetragonal crystal structure with a pure perovskite phase. The [001] oriented single crystal has undergone a series of successive processes to realize them into an array of the transducer element. The oriented crystals were diced and lapped to identical thicknesses. The mechanical polishing process is achieved surface roughness of 1 nm to 2 nm. After polishing the single crystals are annealed at 200° C. to reduce the residual stress that occurred during the aforementioned processes.

In accordance with the embodiments of the present disclosure, the single crystals are subjected to the electrical contact poling process in a silicone oil bath at room temperature. The poling field is applied in the order of 1.5 times of coercive field (5.25 kV/cm to 6.0 kV/cm) and subjected to the field cooling technique. PZN-PT single crystal exhibits the longitudinal piezoelectric strain coefficient of 2000 pC/N to 2100 pC/N with a strain of about 0.10% to 0.12% which is closer to the value of 91PZN-9 PT single crystal. This value is higher than the conventional piezo ceramics. Electromechanical coupling of PZN-PT single crystals in a silver mode of vibration shows the value of k₃₃′=0.73-0.75 respectively.

PZN-PT single crystal poled along [001] direction of the present disclosure showed the hysteresis-free behaviour after poling which confirms 4R engineered domain configuration. Ultra-high piezoelectric coefficient, strain with minimal hysteresis and large electromechanical coupling factor makes them inevitable next-generation material for piezo MEMS-based underwater devices. PZN-PT single crystals are used for fabricating high-frequency (100 kHz to 200 kHz) underwater acoustic transducers and the fabricated acoustic transducer shows ~10 dB enhancement in their receiving sensitivity as compared with conventional PZT based 1-3 piezo composites.

The present disclosure is further illustrated herein below with the help of the following examples. The examples used herein are intended merely to facilitate an understanding of ways in which the embodiments herein may be practised and to further enable those of skill in the art to practice the embodiments herein. Accordingly, the examples should not be construed as limiting the scope of embodiments herein.

### Experimental Details

### Example 1: Preparation of PZN-PT Single Crystal in Accordance With the Present Disclosure

High purity (99.95%) PbO, ZnO, Nb₂O₅ and TiO₂ were weighed and mixed. The flux to charge was taken in the ratio of 55 mol % PbO: 45 mol % PZN-PT to obtain a mixture. The 91PbZn_{1/3}Nb_{2/3}—9PbTiO₃ single crystals grown at morphotropic phase boundary (MPB) composition. The quantities of the individual precursors are ~245 g of Lead (II) Oxide, ~12.6 g of Zinc oxide, ~41.4 g of Niobium (V) oxide, ~1.8 g of Titanium oxide. The mass % of each of the precursors are 84.9204% PbO: 3.3842% ZnO: 11.0531% Niobium (V) oxide: 0.6423% Titanium oxide.

300 g of the above mixture was packed in to a platinum crucible (120 cc with 1 mm wall thickness and 250 g weight) and the crucible was covered with a platinum lid, in order to prevent PbO evaporation. The loaded crucible was fitted into Al₂O₃ crucible and enclosed by Al₂O3 crucible and covered by Al₂O₃ lid, to prevent the damage of the heating module from PbO vapour by breakage of platinum crucible. This arrangement lead to a reduction of PbO weight-loss to less than 2% in an overall growth period of 700 hours.

The alumina crucible was loaded into the required temperature gradient region of the developed flux crystal growth system. The temperature was increased to 1240° C. to 1260° C. at the rate of 70° C./h and was further maintained for 5 hours. The 1 l/min gas flow rate was maintained throughout the crystal growth run and the gas feed at centre of the bottom crucible reduced the number of multi-nuclei. This process induced the growth of a single crystal at the centre of the platinum crucible. By this arrangement, a large inverse temperature gradient (~50° C.) between the crucible bottom and top was imparted such that growth was initiated at the base of the crucible. After soaking at elevated temperature, the growth system was cooled to 900° C. at a cooling rate of 1° C./h. The crucible was decanted at 900° C. after which a faster cooling (60° C./h) was employed till the room temperature was attained. The total growth duration was about 30 days. The crystals were separated from the solidified flux by leaching boiling 30% concentrated nitric acid from the remaining flux in the platinum crucible.

### Observation and Inference

It was observed that large dimension device quality PZN-PT crystals were grown.

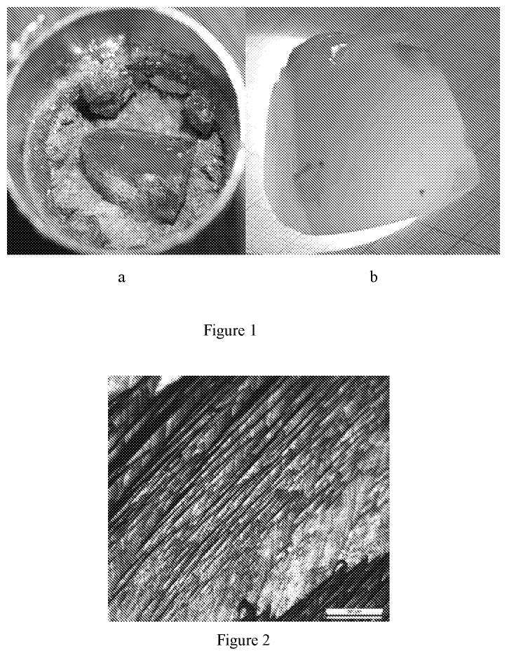

The large-size PZN-PT single crystals (>35mm edge length) were grown using the above methodology with translucent and light yellow exhibiting prominent [001] habitual facets as shown in FIG. 1.

The as-grown crystal displayed natural facets and the dimension of the grown crystal was ~35 mm×30 mm×20 mm. The weight of the crystal was 103 g (FIG. 1).

The as-grown crystals demonstrated that the atomically flat faces occurred only when the crystal grown was in a stable mode from a high-temperature solution and crystal growth occurred by spreading of the layers which are shown in FIG. 2.

### Example 2: Comparison of Orienting, Dicing and Polishing the PZN-PT Single Crystal Element Obtained in Example 1, in Accordance With the Present Disclosure With the Conventionally Prepared PZN-PT Single Crystal Element

An appropriate dimension of PZN-PT single crystals was used in various devices and for these device developments, single crystal elements had undergone various sample preparation processes.

The conventionally prepared PZN-PT single crystals were subjected to orientation and cutting process along [001] to attain desired dimensions.

It was observed that the cutting of the conventionally prepared PZN-PT single crystals led to undesirable defects such as flaws, cracks, or other damages. These defects appeared below the surface of PZN-PT single crystals at a depth of about 200 nm. Further, the effect of the cutting process in these PZN-PT single crystals caused a reduction in the mechanical strength of the crystals and limited their expected lifetime in practical applications.

The PZN-PT single crystals prepared in accordance with Example 1 were subjected to cutting and further polishing. The as-grown PZN-PT single crystal was mounted on a graphite plate using crystal mounting wax and it was subjected to Laue diffraction measurements to orient along [001] direction. The oriented crystals were diced into proper dimensions by using 0.1 mm diamond wire saw cutting system (STX-203, MTI Corporation, California, USA), at the rate of 0.3 mm/min. During the dicing process, the de-ionised water was flowing on the crystal to avoid heat generation.

Diced crystals were mounted on the centre of the polishing alumina disk and dummy crystals were mounted at the corner of the disk using crystal mounting wax. The single crystal surface was flattened using a series of Silicon carbide (SiC) abrasive sheets with a grit size of SiC 800 and SiC 2000.

For crystal side surface polishing and reducing the dummy crystal samples, diced PZN-PT crystals were moulded using a cold mounting process. The mould was made with a cold mounting resin (Technovit 5071) which comprised two component liquid-powder system and it was mixed in a ratio of 1:1. The cold mounting resins had the advantage of mould formation and after polishing PZN-PT crystals were removed from the mould by immersing it into acetone for approximately 12 hours.

The polishing process was a crucial step to remove the damaged surface layer. The strained layer was caused by crystal processing during the cutting and lapping processes. The mechanical polishing process was employed in which the surface layer was fine-tuned to a so-called ‘mirror finish surface’.

The polishing process may certainly produce a ‘surface deformed layer’ that was due to the usage of SiC abrasive lapping sheets with a particle size larger than (1-3) μm. This damaged surface layer formation was owing to intense compression during the polishing processes, which was thought to be composed of a heavily stressed structure in tetragonal symmetry. The surface-deformed layer had different mechanical properties from the interior layer which lies below the ‘surface deformed layer’. The intense compression during the cutting, lapping and polishing process also caused a change in the surface domain structures which was related to the formation of a ‘surface deformed layer’ in the piezoelectric materials. To evade the above consequences, a controlled polishing process using a particle size of 0.03 μm was used to eliminate the undesirable defects in the surface layer.

The polishing process was carried out using diamond paste with a particle size of 1 μm and the surface process finished with 0.03 μm Al₂O₃ powder suspended in water. Both diamond paste and Al₂O₃ slurry were used on soft polishing cloths to attain the single crystal surface of optical quality. The main objective of using Al₂O₃ slurry for the polishing process was to remove the distorted crystal structure below the crystal surface because of intense compression during the sample preparation process. The polished crystals were subjected to an annealing process at 200° C. to reduce the residual stress that occurred during prior processes.

### Example 3: Method of Making the Electrical Contact for PZN-PT Single Crystal Element Prepared in Accordance With the Present Disclosure

For electrical contacts, Au/Cr of 300/30 nm thickness was sputtered onto both the operative surfaces of PZN-PT single crystal element in the plane perpendicular to the thickness direction by DC magnetron sputtering.

The PZN-PT single crystal was subjected to a conventional organic cleaning process to make sure that the surface was cleaned sufficiently enough for electrical contact making. The other sides were protected from electrode deposition to avoid the short circuit between the top and bottom electrodes.

The deposition of the transition metal layer (Cr) and metal layer (Au) on the PZN-PT single crystal was carried out using a DC magnetron sputtering system (Mini Lab 060, Moorfield, Manchester U.K.). The chromium was interlayered between PZN-PT single crystal and gold (Au) top layer.

The process of deposition is defined as below.

PZN-PT single crystal elements were mounted on the 4-inch substrate holder which was placed inside the sputtering chamber. Au/Cr circular target (99.99% purity) of 50.8 mm diameter with 1.6 mm thickness was mounted on the two cylindrical magnetrons which faced opposite to each other with an off-axis angle 15°. The main chamber was evacuated using the turbo molecular pump for the vacuum of about 5×10⁻⁶ mbar. The Au and Cr target were cleaned with an isopropanol solution to avoid contaminants.

The distance between sources (Au/Cr) to the substrate (PZN-PT crystal) was kept constant at about 15 cm and sputter growth was carried out in high purity argon (Ar) gas atmosphere. Ar acted as carrier gas and it ionized into Ar⁺ by secondary electrons which ejected the target atoms towards the substrate. For the ignition of plasma Ar pressure of 40 μbar and DC power, 85 W was applied and high pressure of Ar gas was required for the self-sustainable plasma.

The plasma power (100 W) was used for Au/Cr deposition and substrate rotation of 5 rpm was maintained throughout the deposition to maintain the uniform thickness across the single crystal element. Both Au and Cr deposition were done at room temperature. After reaching the base pressure of 5×10⁻⁶ mbar, Ar gas was passed inside the chamber plasma ignition where the pressure reaches about 2.5×10⁻² mbar. For the deposition, the pressure was again reduced to 10×10⁻³ mbar for Au and Cr deposition.

Cr was deposited on PZN-PT single crystal element followed by Au deposition without breaking vacuum. The 30 nm thick Cr and 300 nm thick Au layers were deposited on PZN-PT single crystal element.

### Example 4: Method of Poling the PZN-PT Single Crystal Element in Accordance With the Present Disclosure

PZN-PT single crystals were subjected to the poling process for different electric field strengths at room temperature for 30 min in a silicon oil bath setup. The DC voltage was applied using a high voltage power supply poling set-up (aixACCT Systems GmbH, Aachen, Germany).

Poling is the process by which aligning the electric dipoles i.e., ‘polarization reversal’ in the direction of the external electric field. PZN-PT single crystals have intrinsic anisotropic nature i.e., direction-dependent properties, poling is a vital process where poled along different directions exhibits different electromechanical properties. PZN-PT single crystals poled along its polar direction have ‘mono-domain state’, whereas poled along other than polar direction exists with multiple domain configurations. However, in PZN-PT single crystals with multiple domain configurations possess extraordinarily large piezoelectric coefficients for the longitudinal vibration mode, while crystals with single domain states are found to possess very low longitudinal properties and ultrahigh shear properties. The electric field, temperature and poling duration are three crucial factors which impact the poling process. So, it is essential to optimize the poling condition in order to acquire the optimal piezoelectric properties.

The electrical contact poling method was used to pole the PZN-PT single crystals where the Au metal electrodes were directly in contact with the electrical probes. The constant electric field i.e., direct current (DC) was applied between the electrodes where the field increased starting from 25 V to a few kV with the step size of 100 V in 5 minutes. The current flowing between the electrodes was mandatorily maintained below 1 μA. After soaking the sample at poling voltage for 30 minutes, the voltage was reduced with the step size of 100 V in 5 minutes. Since the T_{c}/T_{R-T} for the PZN-PT single was relatively low, poling temperature for all the poling processes was fixed at room temperature. The poling field was varied in terms of coercive field and the optimum poling field is obtained at 1.5 times the coercive field.

### Example 5: Characterization of an Array of Piezoelectric Single Crystal Transducer Elements Manufactured in Accordance With Examples 1-4

The structural properties of an array of piezoelectric single crystal elements were investigated by Rigaku glancing incidence X-ray diffraction (GIXRD) using CuK α radiation (λ=0.15418 nm), which was operated at 40 kV and 30 mA and Laue diffraction pattern is recorded at room temperature.

Ferroelectric properties of metallized single crystals were examined by TF analyser 2000 Ferroelectric Tester (aixACCT Systems GmbH, Aachen, Germany). The electric fields were applied between the top and bottom Au electrodes and the crystal is immersed in the silicon oil bath to escape from electric arcing. The sinusoidal bipolar electric field of 6 kV/cm at 1 Hz frequency was applied using a high voltage amplifier (10/10B-HS, Trek, Inc. New York, USA).

The longitudinal piezoelectric strain coefficient (d₃₃) was measured on the basis of the indirect piezoelectric effect from the unipolar strain loop. The unipolar strain response was measured as a function of the electric field at the frequency range of 1 Hz using a single-beam Laser interferometer system (aixACCT Systems GmbH, Aachen, Germany). The impedance characteristics as a function of frequency were measured using a precision impedance analyzer (Agilent 4294A, California, USA)

### Structural Analysis

The structural properties of an array of piezoelectric single crystal transducer elements were studied by X-ray diffraction analysis. From the X-ray diffraction pattern, structural properties like phase purity and crystallinity across the single crystal element was studied. The powder X-ray diffraction studies on PZN-PT single crystal element were examined using a Rigaku X-ray diffractometer equipped with graphite-monochromatic CuKα radiation of wavelength 0.15418 nm, operated at 40 kV and 30 mA. All the powder XRD patterns are recorded at the 0-20 mode in the range of 10° to 70°. The scan speed and step sizes are 2°/min and 0.01° respectively. The XRD patterns were analysed using X'Perthigh score plus software and it compared with JCPDS data.

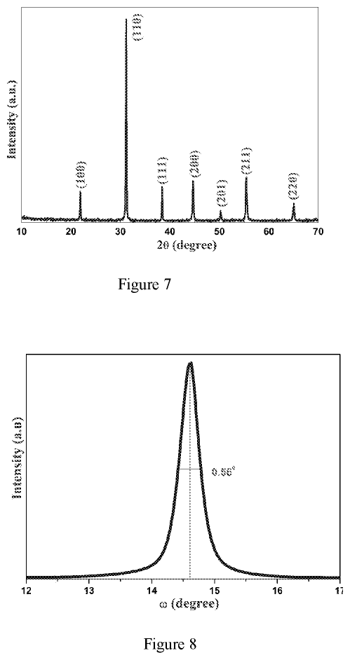

From the powder XRD pattern (FIG. 7), it is inferred that the PZN-PT single crystal was in a perovskite structure with the absence of a defect pyrochlore phase. The X-ray diffraction (200) peak at the value of 2θ=43.9° suggests that PZN-PT single crystal is in the tetragonal phase. The full width at half maximum (FWHM) is calculated from the XRD pattern was in the range of 0.54° to 0.56° revealing that the PZN-PT single crystals of good quality.

From Laue diffraction pattern the grown crystals were oriented along the three mutually orthogonal directions [<100>, <010>and [001]] namely a, b, and c directions (FIG. 6). The backscattered Laue diffraction pattern for three different orientations were simulated using ORIENTEXPRESS software and matched with the recorded Laue diffraction pattern.

### Electrical Properties

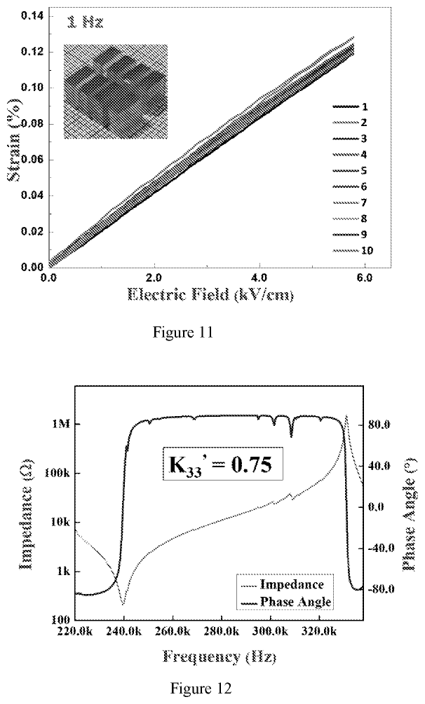

The electric field dependence on polarization of PZN-PT single crystal is presented in FIG. 11. The Electric field is varied from 0-6.0 kV/cm for the frequency of 1 Hz at room temperature. The hysteresis loop is well-saturated and a large value of remnant polarization suggests that it has strong ferroelectric in nature. The hysteresis loop is symmetric about zero electric fields. The polarization response with respect to the external electric field remains the same for both polarities of an electric field. The resultant values of remnant polarization are 24-27.5 μC/cm² and the coercive field is 3.5-4.0 kV/cm.

The unipolar strain versus electric field behaviour was measured on the basis of the converse piezoelectric effect and it is exhibited in FIG. 11. The converse strain experiments were carried out after poling at room temperature on a 1 Hz frequency.

From the strain versus electric field curves, it is inferred that the strain values are zero after removing the electric field i.e., ΔS_{E=0}=0. It implies that the no depoling effect occurs in the PZN-PT crystal after poling. The unipolar strain-electric field curve displays nearly an hysteresis behaviour and the strain value upsurges linearly with an electric field of 6.0 kV/cm. The maximum strain observed is 0.10 % to 0.12 %. The longitudinal piezoelectric strain coefficient is 2000 pm/V to 2100 pm/V was evaluated from the slope of the strain-electric field response curve. The area of the strain-electric field response curve specifies that PZN-PT single crystals are in the vicinity of morphotropic phase boundary (MPB) composition.

The impedance and phase angle of PZN-PT single crystal measured is shown in FIG. 13. The impedance and phase angle were measured from the frequencies in the range of 40 Hz to 1 MHz. The fundamental resonant frequency of thickness mode vibration at minimum impedance is 240 kHz to 242 kHz and the anti-resonant frequency at maximum impedance was 335 kHz to 340 kHz. The magnitude of impedance in the order of 10³ Ω to 10⁶ Ω indicates that the crystal element remained in resistive nature even after poling process and the de-poling effect did not occur.

### Example 6: Fabrication and Evaluation of PZN-PT Single Crystal of the Present Disclosure Based High Frequency Underwater Acoustic Transducer

### Methods

PZN-PT single crystals of the size 4.5 mm×2.5 mm×4.2 mm were used to make a linear array of eight elements. The dimension of the PZN-PT single crystals is chosen to exhibit a resonance frequency greater than 200 kHz and a frequency difference of about greater than 80 kHz between resonance and anti-resonance frequencies. All the elements were assembled in Teflon housing and the entire assembly was moulded with acoustically transparent polyurethane to a thickness of 15 mm. The transducer elements were backed with a pressure release material followed by hard backing and connected with low noise two core shielded twisted pair wires.

It was observed that after moulding, the resonance frequencies of the PZN-PT single crystals were reduced by 70 kHz due to the loading effect of moulding. Moreover, moulding also reduced the sharpness of resonance and made it wider. The same phenomenon was observed in the case of 1-3 piezo composites.

The transducer array was calibrated in an acoustic tank in the frequency band of 50 kHz to 350 kHz, using the second calibration method. The receiving sensitivity (RS) of the PZN-PT single crystal elements array was plotted with respect to frequency and compared with the receiving sensitivity of 1-3 piezo composites, as shown in FIG. 14.

In the frequency region 100 kHz to 200 kHz, the receiving sensitivities (−210 to −215 dB ref 1 V/μPa without pre-amplifier) of PZN-PT single crystals showed ~10 dB enhancement as compared with 1-3 piezo composites.

### TECHNICAL ADVANCEMENTS

The present disclosure described herein above has several technical advantages including, but not limited to, the realization of a piezoelectric single crystal transducer element, wherein the transducer element, that:
have exceptionally high
   longitudinal piezoelectric strain coefficient d₃₃>2000 pC/N;
   electromechanical coupling factor k₃₃>90%, low hysteresis strain >1%; and
   high dielectric coefficient ε>5000 at morphotropic phase boundary (MPB) condition with specific orientation and domain-engineered configuration;
ability to replace conventional PZT ceramics in strategic defence applications due to its exceptional properties.
   and
   a method for the manufacturing of the piezoelectric single crystal transducer element, wherein the method:
is simple and advanced;
is competitively economical;
is commercially scalable;
controlled spontaneous nucleation; and
has a comparatively higher growth rate.

PZN-PT single crystal elements show good compositional homogeneity, which leads to very fewer fluctuations in its electrical properties that are less than three per cent (3%) element-to-element property variation. The uniform electrical properties across each single crystal element are very much demanded in strategic and commercial applications for precise and identical device responses.

This array of piezoelectric single crystal transducer elements is an integral part of underwater SONAR, ultrasound medical transducers, low-field driven actuators, electroacoustic transducers and other next-generation piezoelectric based MEMS devices.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the invention to achieve one or more of the desired objects or results. While certain embodiments of the inventions have been described, these embodiments have been presented by way of example only, and are not intended to limit the scope of the inventions. Variations or modifications to the formulation of this invention, within the scope of the invention, may occur to those skilled in the art upon reviewing the disclosure herein. Such variations or modifications are well within the spirit of this invention.

The numerical values given for various physical parameters, dimensions and quantities are only approximate values and it is envisaged that the values higher than the numerical value assigned to the physical parameters, dimensions and quantities fall within the scope of the invention unless there is a statement in the specification to the contrary.

While considerable emphasis has been placed herein on the specific features of the preferred embodiment, it will be appreciated that many additional features can be added and that many changes can be made in the preferred embodiment without departing from the principles of the disclosure. These and other changes in the preferred embodiment of the disclosure will be apparent to those skilled in the art from the disclosure herein, whereby it is to be distinctly understood that the foregoing descriptive matter is to be interpreted merely as illustrative of the disclosure and not as a limitation.

1. A piezoelectric single crystal transducer element, said piezoelectric single crystal transducer element comprising:
a PZN-PT single crystal having predetermined dimensions and having an operative top surface and an operative bottom surface; and
b at least one metallized layer of predetermined thickness on said operating top surface and said operating bottom surface,
wherein said crystal is poled along [001] direction.

2. The transducer element as claimed in claim 1, wherein said dimensions of said transducer element piezoelectric single crystal are in the range of 35×30×20 mm³ to 40×40×30 mm³.

3. The transducer element as claimed in claim 1, wherein said metallized layer comprises at least one metal selected from gold and chromium; and a thickness of said metallized layer is in the range of 250 nm to 350 nm.

4. The transducer element as claimed in claim 1, is characterized by having:
a. a remnant polarization in the range of 24 μC/cm² to 27.5 μC/cm² at the frequency of 1 Hz;
b. a coercive field in the range of 3.5 kV/cm to 4.0 kV/cm at the frequency of 1 Hz;
c. a unipolar strain in the range of 0.125% to 0.128 % at a frequency of 1 Hz;
d. a longitudinal piezoelectric strain coefficient d₃₃ in the range of 2000 pm/V to 2100 pm/V at a frequency of 1 Hz;
e. an electromechanical coupling coefficient k₃₃′ in the silver mode of vibration is in the range of 73% to 75%; and
f. a longitudinal voltage coefficient g₃₃ in the range of 42 mV.m/N to 50 mV.m/N.

5. The transducer element as claimed in claim 1, is adapted to use in a high-frequency underwater acoustic transducer having a frequency in the range of 100 kHz to 200 kHz as an integral part of underwater SONAR, ultrasound medical transducers, low-field driven actuators, electroacoustic transducer and piezoelectric based MEMS devices.

6. The transducer element as claimed in claim 1, wherein said transducer element when used in high-frequency underwater transducers having a frequency in the range of 100 kHz to 200 kHz shows more than ~10 dB improvement in receiving sensitivity than the 1-3 piezo composites.

7. A method for manufacturing a piezoelectric single crystal transducer element comprising:
a. preparing a PZN-PT single crystal;
b. orienting said PZN-PT single crystal along a predetermined direction to obtain an oriented PZN-PT single crystal;
c. sequentially, dicing, lapping and polishing said oriented PZN-PT single crystal to obtain a PZN-PT single crystal having predetermined dimensions, and having an operative top surface and an operating bottom surface;
d. depositing a metallized layer on said operative top surface and said operating bottom surface of said PZN-PT single crystal having predetermined dimensions to obtain a metallized crystal; and
e. poling said metallized crystal along said predetermined direction to obtain the piezoelectric single crystal transducer elements.

8. The method as claimed in claim 7, wherein said PZN-PT single crystal in step (a) is prepared by using the following steps:
a. mixing predetermined amounts of a lead precursor, a zinc precursor, a niobium precursor and a titanium precursor to obtain a mixture;
b. placing said mixture into a noble metal confinement having a gas inlet and a gas outlet, followed by placing said noble metal confinement into an alumina confinement;
c. heating said alumina confinement to a first predetermined temperature at a predetermined heating rate, and simultaneously feeding a gas at a predetermined flowrate through said noble metal confinement, followed by maintaining said first predetermined temperature for a first predetermined time period to obtain a preform; and
d. cooling said preform at a second predetermined temperature at a predetermined cooling rate to obtain said PZN-PT single crystal.

9. The method as claimed in claim 8, wherein
said lead precursor is lead oxide;
said zinc precursor is zinc oxide;
said niobium precursor is niobium oxide; and
said titanium precursor is titanium oxide.

10-12. (canceled)

13. The method as claimed in claim 8, wherein said gas is oxygen; and said predetermined gas flowrate is in the range of 0.7 l/min to 2 l/min.

14. The method as claimed in claim 8, wherein
said predetermined amount of said lead precursor is in the range of 81 mass % to 82 mass % with respect to the total amount of said mixture;
said predetermined amount of said zinc precursor is in the range of 4.0 mass % to 4.5 mass % with respect to the total amount of said mixture;
said predetermined amount of said niobium precursor is in the range of 13 mass % to 14 mass % with respect to the total amount of said mixture; and
said predetermined amount of said titanium precursor is in the range of 0.5 mass % to 1.2 mass % with respect to the total amount of said mixture.

15-17. (canceled)

18. The method as claimed in claim 8, wherein said noble metal confinement is a noble metal crucible with a noble metal lid, wherein said noble metal is at least one selected from platinum and iridium; and said alumina confinement is an alumina crucible with an alumina lid.

19. (canceled)

20. The method as claimed in claim 8, wherein said first predetermined temperature is in the range of 1240° C. to 1260° C.; said predetermined heating rate is in the range of 60° C./hour to 80° C./hour; and said first predetermined time period is in the range of 4 hrs to 6 hrs.

21. (canceled)

22. The method as claimed in claim 8, wherein said second predetermined temperature is in the range of 880° C. to 920° C.

23. (canceled)

24. The method as claimed in claim 8, wherein said predetermined cooling rate is in the range of 0.9° C./hour to 1° C./hour.

25. (canceled)

26. The method as claimed in claim 7, wherein said predetermined direction of orientation is [001], and said orienting in step (b) is performed using a backscattered Laue diffraction technique.

27. The method as claimed in claim 7, wherein said oriented PZN-PT single crystal after said dicing, lapping and polishing have predetermined dimensions in the range of 35×30×20 mm³ to 40×40>30 mm³.

28. The method as claimed in claim 7, where said depositing of a metallized layer in step (d) is performed by using a DC magnetron sputtering process.

29. The method as claimed in claim 28, wherein said DC magnetron sputtering is performed with power in the range of 80 W to 100 W at a room temperature for a time period in the range of 3 minutes to 5 minutes.

30. The method as claimed in claim 8, wherein poling of said metallized crystal is done by subjecting said metallized crystal to the electrical contact poling process to attain multi-domain 4R engineered state by using field cooling technique, wherein a poling field is applied in the order of 1.5 times of coercive field in the range of 5.25 kV/cm to 6.0 kV/cm at a room temperature.
